(19) United States
(12) Patent Application Publication
(10) Pub. No.: US 2022/0026937 A1
(43) Pub. Date: Jan. 27, 2022

(54) TEMPERATURE CONTROL SYSTEM AND TEMPERATURE CONTROL METHOD

(71) Applicant: CHANGXIN MEMORY TECHNOLOGIES, INC., Hefei (CN)

(72) Inventor: Xianyong YU, Hefei (CN)

(21) Appl. No.: 17/386,712

(22) Filed: Jul. 28, 2021

Related U.S. Application Data
(63) Continuation of application No. PCT/CN2021/092910, filed on May 10, 2021.

(30) Foreign Application Priority Data
Jul. 21, 2020 (CN) 202010704689.1

(51) Int. Cl. G05D 23/19; H01L 21/67; G03F 7/20

(52) U.S. Cl. CPC G05D 23/1927; G03F 7/70875; H01L 21/67248

(57) ABSTRACT

A temperature control system and method are provided. The temperature control system includes: a bearing platform including a central platform and multiple edge platforms arranged around same; multiple temperature control modules each connected to a respective edge platform and configured to regulate temperature of a corresponding region of a wafer on the edge platform; a parameter acquisition module configured to acquire temperatures of the wafer; and a processing module configured to acquire a temperature abnormal region of the wafer and regulate a temperature of the temperature control module corresponding to the temperature abnormal region. The parameter acquisition module is used to acquire the temperatures of the wafer on the bearing platform, to acquire the temperature abnormal region of the wafer. Then, the processing module acquires the corresponding temperature control module based on the position of the temperature abnormal region. The temperatures at specific positions of a wafer are accurately controlled.

### CROSS-REFERENCE TO RELATED APPLICATION

The present application is a continuation of International Application No. PCT/CN2021/092910, filed on May 10, 2021, which claims priority to Chinese patent application No. 202010704689.1, filed on Jul. 21, 2020 and entitled “Storage Container and Supply System”. The contents of International Application No. PCT/CN2021/092910 and Chinese patent application No. 202010704689.1 are incorporated herein by reference in their entireties.

### TECHNICAL FIELD

The disclosure relates to the field of semiconductors, and in particular to a temperature control system and a temperature control method.

### BACKGROUND

Since an integrated circuit is formed by overlapping many circuit boards, the precision (i.e. precision of Overlay (OVL)) of aligning each circuit board and a previous circuit board or a subsequent circuit board must be ensured to be within a preset range. If the OVL value exceeds the preset range, the whole integrated circuit may not complete the designed work. Therefore, in the process of manufacturing each circuit board of the integrated circuit, the OVL of the present circuit board and a previous circuit board should be measured.

However, the applicant has found that when OVL measurement is performed for a wafer, due to the thermal expansion and contraction effect caused by the temperature the OVL value obtained by the measurement is not accurate when the temperature distribution of the wafer is not uniform.

### SUMMARY

Embodiments of the disclosure provide a temperature control system and a temperature control method, which realize accurate control over the temperature at specific positions of a wafer through multiple sites, thereby ensuring uniform temperature distribution of the wafer.

In order to solve the above problem, the embodiments of the disclosure provide a temperature control system. The temperature control system includes: a bearing platform, which is configured to bear a wafer, and includes a central platform and multiple edge platforms arranged around the central platform; multiple temperature control modules, each connected to a respective edge platform and configured to regulate a temperature of a corresponding region of the wafer on the respective edge platform; a parameter acquisition module, configured to acquire temperatures of the wafer on the bearing platform; and a processing module, configured to acquire a temperature abnormal region of the wafer based on the temperatures of the wafer and regulate a temperature of a temperature control module corresponding to the temperature abnormal region.

Compared with the related art, the parameter acquisition module is used to acquire the temperatures of a wafer on a bearing platform, so as to acquire a temperature abnormal region of the wafer, i.e. to acquire a specific high-temperature position or a specific low-temperature position of the wafer. Then, the processing module acquires a corresponding temperature control module based on the position of the temperature abnormal region. The temperature control module regulates the temperature of the temperature abnormal region of the wafer. The temperature of the specific position of the wafer can be accurately controlled, thereby ensuring the uniform temperature distribution of the wafer.

In addition, each edge platform comprises: a support member having a gas circulation region therein; and the temperature control module connected to the edge platform is configured to introduce gas with a preset temperature into the gas circulation region based on a signal sent from the processing module. The support member includes: a gas extraction hole and a gas intake hole communicated with the gas circulation region, wherein the gas extraction hole is configured to extract gas out of the gas circulation region; and the gas intake hole is configured to introduce the gas with the preset temperature into the gas circulation region. The temperature of the wafer is regulated through gas with a preset temperature in the gas circulation region. The cost is low, and the solution is environment-friendly.

In addition, the support member may include: an edge support portion, a first support portion, and a plurality of discrete second support portions, wherein the edge support portion is arranged around the first support portion, and a gap exists between the edge support portion and the first support portion; and the second support portions are located in the gap, and the gas circulation region is enclosed by the edge support portion, the first support portion, and the second support portions. The temperature control module only performs temperature regulation for the wafer in the corresponding region so as to improve the accuracy of temperature regulation for the wafer.

In addition, the edge platforms arranged around the central platform may form a plurality of concentric rings centered about the central platform. The edge platforms are arranged in a distribution mode of encircling to form concentric rings. The edge platforms are tightly distributed, and the number of sites for temperature control of the wafer by the temperature control modules is increased.

In addition, temperature control modules connected to edge platforms in each concentric ring with a respective different radius have a respective different temperature regulation rate, and temperature control modules connected to edge platforms in a concentric ring having a larger radius have a smaller temperature regulation rate.

In addition, the temperature control system may further include: a constant-temperature pipeline filled with constant-temperature liquid or constant-temperature gas. In addition, the constant-temperature pipeline is located in gaps between the plurality of edge platforms. In addition, the constant-temperature liquid or the constant-temperature gas is in a temperature range of 20° C. to 25° C. The temperature of the wafer is regulated through the constant-temperature pipeline and the constant-temperature liquid, so that the overall temperature of the wafer has a tendency of changing towards the constant-temperature liquid or the constant-temperature gas.

In addition, the parameter acquisition module may include a plurality of temperature sensors arranged at intervals or an infrared temperature sensor, configured to acquire temperatures at a plurality of positions of the wafer on the bearing platform. The processing module further includes a processing sub-module configured to acquire a temperature distribution map of the wafer based on the acquired temperatures of the plurality of positions of the wafer.

The embodiments of the present application also provide a temperature control method, which may be applied to the above temperature control system and may include: acquiring temperatures of a wafer on a bearing platform; acquiring, based on the temperatures of the wafer, a region of the wafer needing temperature regulation; acquiring an edge platform corresponding to the region of the wafer needing temperature regulation; and regulating a temperature of the region of the wafer needing temperature regulation through a temperature control module connected to the edge platform.

In addition, the acquiring, based on the temperatures of the wafer, a region of the wafer needing temperature regulation may include: acquiring a temperature distribution map of the wafer based on temperatures at a plurality of positions of the wafer; and acquiring, based on the temperature distribution map of the wafer, the region of the wafer needing temperature regulation.

In addition, the preset temperature may be in a temperature range of 20° C. to 25° C.

In addition, the temperature control method may further include: regulating the temperatures of the wafer on the bearing platform to a preset temperature through constant-temperature liquid or constant-temperature gas.

In addition, temperature control modules connected to edge platforms in each concentric ring with a respective different radius have a respective different temperature regulation rate, and temperature control modules connected to edge platforms in a concentric ring with a larger radius have a smaller temperature regulation rate.

In addition, the event that temperature control modules connected to edge platforms in a concentric ring with a larger radius have a smaller temperature regulation rate may include: temperature control modules connected to edge platforms in each concentric ring with a respective different radius have a same gas injection flow rate and a respective different gas extraction flow rate, and temperature control modules connected to edge platforms in a concentric ring with a larger radius have a smaller gas extraction flow rate.

Compared with the related art, the temperatures of a wafer on a bearing platform are acquired to acquire a temperature abnormal region of the wafer, i.e. to acquire a specific high-temperature position or a specific low-temperature position of the wafer. Then, an edge platform corresponding to the position of the temperature abnormal region of the wafer is acquired based on the temperatures of the wafer. The temperature of the temperature abnormal region of the wafer is regulated through a temperature control module connected to the edge platform. The temperature at the specific position of the wafer can be accurately controlled, thereby ensuring the uniform temperature distribution of the wafer.

### BRIEF DESCRIPTION OF THE DRAWINGS

FIGS. 1 to 5 illustrate schematic structural diagrams of a temperature control system according to an embodiment of the disclosure.

FIG. 6 illustrates a schematic flowchart of a temperature control method according to another embodiment of the disclosure.

### DETAILED DESCRIPTION

At present, when OVL measurement is performed on a wafer, due to the thermal expansion and contraction effect caused by the temperature, the OVL value obtained by the measurement is not accurate when the temperature distribution of the wafer is not uniform.

In order to solve the above problem, the embodiments of the disclosure provide a temperature control system. The temperature control system includes: a bearing platform, which is configured to bear a wafer, and includes a central platform and multiple edge platforms arranged around the central platform; multiple temperature control modules, each connected to a respective edge platform and configured to regulate a temperature of a corresponding region of the wafer on the respective edge platform; a parameter acquisition module, configured to acquire temperatures of the wafer on the bearing platform; and a processing module, configured to acquire a temperature abnormal region of the wafer based on the temperatures of the wafer and regulate a temperature of a temperature control module corresponding to the temperature abnormal region.

According to an embodiment of the disclosure, accurate control over the temperature at a specific position of a wafer is realized through multiple sites, thereby ensuring uniform temperature distribution of the wafer.

To more clarify the objects, technical solutions, and advantages of the embodiments of the disclosure, various embodiments of the disclosure will be described below in combination with the accompanying drawings. However, those of ordinary skill in the art will appreciate that in various embodiments of the disclosure, numerous technical details are set forth in order to provide readers with a better understanding of the disclosure. However, even without these technical details and various changes and modifications based on the following embodiments, the claimed technical solution of the present application may still be implemented. The following divisions of the various embodiments are for convenience of description and should not be construed as limiting specific implementations of the present application, and the various embodiments may be combined with and refer to each other without contradiction.

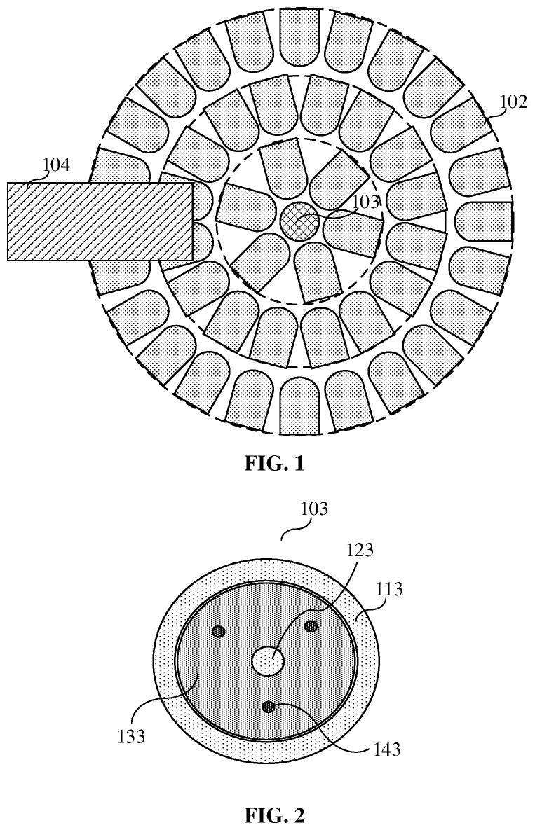

FIGS. 1 to 5 illustrate schematic structural diagrams of a temperature control system according to an embodiment of the disclosure. The temperature control system of the disclosure will be described in detail below.

Referring to FIG. 1, a temperature control system is applied to an exposure machine table.

Specifically, the exposure machine table is configured to measure the OVL of a wafer. During measuring the OVL of the wafer by the exposure machine table, the wafer is firstly conveyed to a bearing platform. The bearing platform includes a central platform 103 and multiple edge platforms 102. The multiple edge platforms 102 are arranged around the central platform 103. The central platform 103 is configured to bear the wafer and rotate carrying the wafer. During rotation of the wafer, a pre-alignment device 104 is configured to acquire the eccentricity of the wafer, acquire a position where the wafer is placed on the bearing platform through the eccentricity, and correct the position where the wafer is placed on the bearing platform subsequently through the eccentricity of the wafer.

In one example, the pre-alignment device 104 includes an edge sensor. During the central platform 103 rotates carrying the wafer, the edge sensor is configured to acquire distances between edge positions of the wafer and the edge sensor so as to acquire a graph of rotation angles of wafer to the distances between the edge positions of the wafer and the edge sensor. An offset distance and an offset angle of the wafer being placed on the bearing platform are acquired according to rotation angles of wafer corresponding to maximum and minimum distances among the distances between the edge positions of the wafer and the edge sensor in the graph, i.e. the eccentricity of the wafer is acquired.

The bearing platform includes a central platform 103. The central platform 103 is configured to bear the wafer and rotate carrying the wafer. In one example, referring to FIG. 2, the central platform 103 includes a first support table 113, a first gas hole 123, a second support table 133, and a second gas hole 143. The first support table 113 is higher than the second support table 133 and is configured to bear the wafer. When the central platform 103 bears the wafer, the first support table 113, the second support table 133, and a bottom surface of the wafer form a sealed space. The first gas hole 123 and the second gas hole 143 are configured to extract gas out of the sealed space or introduce gas into the sealed space. Specifically, when the wafer is placed on the central platform 103, part of gas in the sealed space is extracted out through the first gas hole 123 and the second gas hole 143. A pressure difference is formed between the sealed space and an external environment. The wafer is fixed on the central platform 103 under the action of atmospheric pressure. When the wafer needs to be taken away, gas is supplemented into the sealed space through the first gas hole 123 and the second gas hole 143, so that the pressure difference formed between the sealed space and the external environment is restored, so as to take away the wafer.

It should be noted that the amount of gas to be extracted from the sealed space is determined according to the volume of the sealed space in practical application, in order to fix the wafer onto the center platform 103 by atmospheric pressure. The amount of gas to be extracted from the sealed space through the first gas hole 123 and the second gas hole 143 is not limited in the embodiment.

It should also be noted that there are three second gas holes 143 in FIG. 2, which is an illustration of the number of the second gas holes 143. In specific application, the number of the second gas holes 143 may be set to, e.g., 2, 4, or 5 according to an extraction speed of gas. As the number of the second gas holes 143 is larger, the speed of extracting gas from the sealed space through the second gas holes 143 is higher.

With continued reference to FIG. 1, the bearing platform further includes multiple edge platforms 102. Each edge platform 102 is connected to at least one temperature control module (not shown) for regulating the temperature of a corresponding region of the wafer on the bearing platform.

Specifically, the edge platforms 102 may be distributed at any position on the surface of the exposure machine table. In the disclosure, the multiple edge platforms 102 are arranged around the central platform 103. The edge platforms 102 arranged around the central platform 103 form multiple concentric rings centered about the central platform. Referring to FIG. 1, three concentric rings are illustrated in the disclosure as an example for description. The concentric ring nearest to the center platform 103 is an inner ring, the concentric ring farthest away from the center platform 103 is an outer ring, and the concentric ring between the inner and outer rings is a secondary outer ring. The edge platforms 102 are arranged in a distribution mode of encircling to form concentric rings, and the edge platforms 102 are tightly distributed, to increase the number of sites for temperature control of the wafer by the temperature control modules connected to the edge platforms 102.

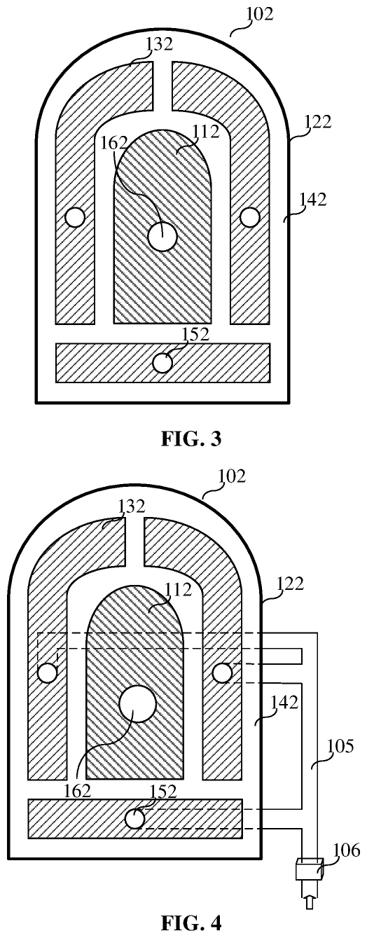

Referring to FIGS. 3 and 4, in the present embodiment, the edge platform 102 includes a support member.

The support member has a gas circulation region 142 therein. In one example, referring to FIG. 3, the support member includes: an edge support portion 122, a first support portion 112, and multiple discrete second support portions 132. The edge support portion 122 is arranged around the first support portion 112, and a gap exists between the edge support portion 122 and the first support portion 112. The second support portions 132 are located in the gap, and the gas circulation region 142 is enclosed by the edge support portion 122, the first support portion 112, and the second support portions 132.

The temperature control module connected to the edge platform 102 is configured to introduce gas with a preset temperature into the gas circulation region 142. The preset temperature is a target temperature for regulating the temperature of the wafer. In the present embodiment, the preset temperature is 22.5° C. since an optimum temperature of the wafer for exposure by the exposure machine table is 22.5° C. In other embodiments, the preset temperature may be a temperature range approximate to the optimum temperature for exposure, e.g. 20° C. to 25° C.

In one example, referring to FIG. 4, the support member further includes: a gas extraction hole 162 and a gas intake hole 152 communicated with the gas circulation region. The gas extraction hole 162 is configured to extract gas out of the gas circulation region 142. The gas intake hole 152 is configured to introduce gas with a preset temperature into the gas circulation region 142. Specifically, the gas intake hole 152 is connected to a gas intake pipeline 105. The gas intake pipeline 105 is configured to supply gas to the gas intake hole 152. A temperature control module 106 is provided on the gas intake pipeline 105, for heating the gas to a preset temperature.

It should be noted that there are three gas intake holes 152 in FIGS. 3 and 4, which is an illustration of the number of the gas intake holes 152. In specific application, the number of the gas intake holes 152 may be set to, e.g., 2, 4, or 5 according to an extraction speed of gas. As the number of the gas intake holes 152 is larger, the speed of extracting gas from the gas circulation region 142 through the gas intake holes 152 is higher, and the effect of temperature regulation via the temperature control module 106 is more uniform.

In the present embodiment, temperature control modules 106 connected to edge platforms 102 in each concentric ring with a respective different radius have a respective different temperature regulation rate, and temperature control modules 106 connected to edge platforms 102 in a concentric ring having a larger radius (the inner ring, the secondary outer ring, and the outer ring in sequence) have a smaller temperature regulation rate. In one example, the temperature regulation rate is controlled by the circulation rate of gas at a preset temperature. Specifically, the gas injection flow rate of the inner ring is 145000 Pa, and the gas extraction flow rate of the inner ring is 22000 Pa. The gas injection flow rate of the secondary outer ring is 145000 Pa, and the gas extraction flow rate of the secondary outer ring is 21850 Pa. The gas injection flow rate of the outer ring is 145000 Pa, and the gas extraction flow rate of the outer ring is 21700 Pa.

It should be noted that the values of the gas extraction flow rate and the gas injection flow rate of each concentric ring described above are provided as examples only, which is intended to represent different temperature regulation rates of the temperature control modules 106 connected to the edge platforms 102 in the concentric rings with different radii in the present embodiment, and does not limit the embodiments of the disclosure. In addition, the gas circulation rate is changed by fixing the gas injection flow rate and changing the gas extraction flow rate in the present embodiment. In other embodiments, the gas circulation rate may be changed by fixing the gas extraction flow rate and changing the gas injection flow rate, or by changing both the gas injection flow rate and the gas extraction flow rate.

The temperature control system further includes: a parameter acquisition module and a processing module.

The parameter acquisition module is configured to acquire temperatures of the wafer on the bearing platform. The processing module is configured to acquire a temperature abnormal region of the wafer based on the temperatures, regulate a temperature of the temperature control module 106 connected to the edge platform 102 corresponding to the temperature abnormal region on the bearing platform, and indirectly control the temperature of the wafer in the temperature abnormal region by changing the temperature of the temperature control module 106.

Specifically, the parameter acquisition module includes multiple temperature sensors arranged at intervals or an infrared temperature sensor, configured to acquire temperatures of multiple positions of the wafer on the bearing platform. That is, the parameter acquisition module may be implemented in the following two approaches.

Approach 1, the parameter acquisition module is an infrared temperature sensor. The temperatures of the wafer on the bearing platform are acquired through the infrared temperature sensor. A temperature distribution map of the wafer may be directly acquired due to the heat sensitive property of the infrared temperature sensor.

Approach 2: the parameter acquisition module is multiple temperature sensors arranged at intervals. The multiple temperature sensors are configured to acquire the temperatures at multiple positions of the wafer on the bearing platform. In such a case, the processing module further includes a processing sub-module which is configured to acquire a temperature distribution map of the wafer based on the acquired temperatures at the multiple positions of the wafer. The specific temperature distribution of the wafer may be accurately acquired by acquiring a wafer distribution map, and the temperature abnormal region of the wafer may be more accurately acquired.

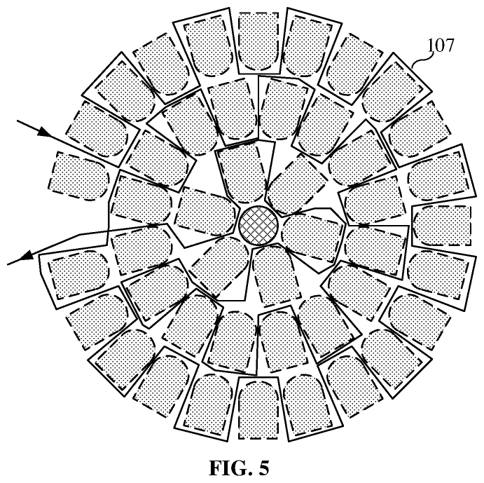

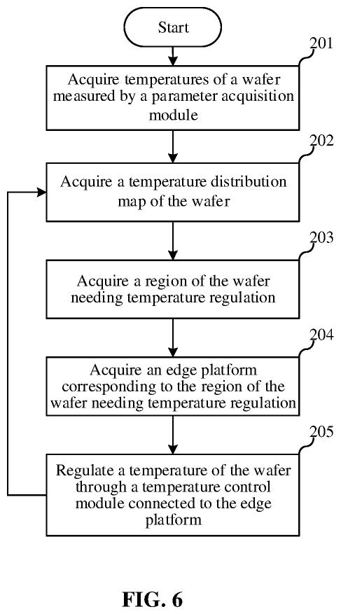

In addition, referring to FIG. 5, in the present embodiment, the temperature control system further includes a constant-temperature pipeline 107. The constant-temperature pipeline 107 is filled with constant-temperature liquid or constant-temperature gas for directionally changing the temperature of the wafer on the bearing platform. The temperature of the wafer is changed towards the constant-temperature liquid or the constant-temperature gas. Specifically, in one example, the constant-temperature pipeline 107 is located in the gap between multiple edge platforms, i.e. the constant-temperature pipeline 107 is arranged around the edge platforms, thereby greatly covering the area of the wafer on the bearing platform and having a better temperature control effect on the whole wafer. The constant-temperature liquid or the constant-temperature gas is in a temperature range of 20° C. to 25° C., e.g., 21° C., 22° C., 23° C., and 24° C. In the present embodiment, the temperature of the constant-temperature liquid or the constant-temperature gas is 22.5° C. since an optimum temperature of the wafer for exposure by the exposure machine table is 22.5° C. The temperature of the whole wafer is changed towards 22.5° C., so that the wafer is at the optimum temperature during exposure, and the efficiency of subsequent wafer exposure is improved.

Compared with the related art, the parameter acquisition module is used to acquire the temperatures of a wafer on a bearing platform, so as to acquire a temperature abnormal region of the wafer, i.e. to acquire a specific high-temperature position or a specific low-temperature position of the wafer. Then, the processing module acquires a corresponding temperature control module based on the position of the temperature abnormal region. The temperature control module regulates the temperature of the temperature abnormal region of the wafer. The temperature of the specific position of the wafer can be accurately controlled, thereby ensuring the uniform temperature distribution of the wafer.

It is worth noting that units referred to in the present embodiment are logical units. In practical application, a logical unit may be a physical unit or a part of a physical unit, or may be implemented with a combination of physical units. In addition, in order to highlight the innovative portion of the disclosure, units not closely related to solving the technical problems set forth in the disclosure have not been introduced in the present embodiment, but this does not indicate that other units do not exist in the present embodiment.

Another embodiment of the disclosure relates to a temperature control method.

The temperature control method is applied to the above temperature control system and includes the following actions. Temperatures of a wafer on a bearing platform are acquired. A region of the wafer needing temperature regulation is acquired based on the temperatures of the wafer. An edge platform corresponding to the region of the wafer needing temperature regulation is acquired. A temperature of the region of the wafer needing temperature regulation is regulated through a temperature control module connected to the edge platform.

Referring to FIG. 6, the temperature control method provided in the present embodiment will be described in detail with reference to the accompanying drawings, and descriptions of the same or corresponding parts as those in the above embodiment will not be described again hereinafter.

In 201, temperatures of a wafer measured by a parameter acquisition module are acquired.

In the present embodiment, the method further includes the following action 202: a temperature distribution map of the wafer is acquired.

Specifically, the temperatures of a wafer are measured by a parameter acquisition module. The parameter acquisition module includes multiple temperature sensors arranged at intervals or an infrared temperature sensor, configured to acquire the temperatures at multiple positions of the wafer on the bearing platform. That is, the parameter acquisition module may be implemented in the following two approaches.

Approach 1, the parameter acquisition module is an infrared temperature sensor. The temperatures of the wafer on the bearing platform are acquired through the infrared temperature sensor. A temperature distribution map of the wafer may be directly acquired due to the heat sensitive property of the infrared temperature sensor.

Approach 2: the parameter acquisition module is multiple temperature sensors arranged at intervals. The multiple temperature sensors are configured to acquire the temperatures at multiple positions of the wafer on the bearing platform. In such a case, the processing module further includes a processing sub-module which is configured to acquire a temperature distribution map of the wafer based on the acquired temperatures at the multiple positions of the wafer. The specific temperature distribution of the wafer may be accurately acquired by acquiring a wafer distribution map, and the temperature abnormal region of the wafer may be more accurately acquired.

In step 203, a region of the wafer needing temperature regulation is acquired.

In the present embodiment, the specific temperature distribution of the wafer may be accurately acquired by acquiring a wafer distribution map, so that the temperature abnormal region of the wafer can be more accurately acquired. In other embodiments, it is also possible to proceed directly to action 203 through action 201, i.e. a region of the wafer needing temperature regulation is acquired directly through the temperatures of the wafer acquired by the parameter acquisition module.

In step 204, an edge platform corresponding to the region of the wafer needing temperature regulation is acquired.

In step 205, a temperature of the wafer is regulated through a temperature control module connected to the edge platform.

Specifically, the processing module is configured to acquire a temperature abnormal region of the wafer based on the temperature distribution map, i.e. the region of the wafer needing temperature regulation, and acquire a temperature control module corresponding to the region according to the region of the wafer needing temperature regulation. The temperature of the temperature control module on the bearing platform corresponding to the temperature abnormal region is regulated. The temperature of the wafer in the temperature abnormal region is indirectly controlled by changing the temperature of the temperature control module.

In one example, the edge platform includes a support member. The support member has a gas circulation region therein. The temperature control module connected to the edge platform is configured to introduce gas with a preset temperature into the gas circulation region. The preset temperature is a target temperature for regulating the temperature of the wafer. In the present embodiment, the preset temperature is 22.5° C. since an optimum temperature of the wafer for exposure by the exposure machine table is 22.5° C. In other embodiments, the preset temperature may be a temperature range approximate to the optimum temperature for exposure, e.g. 20° C. to 25° C.

Specifically, the support member includes: a gas extraction hole and a gas intake hole communicated with the gas circulation region. The gas extraction hole is configured to extract gas out of the gas circulation region. The gas intake hole is configured to introduce gas with a preset temperature into the gas circulation region. Specifically, the gas intake hole is connected to a gas intake pipeline. The gas intake pipeline is configured to supply gas to the gas intake hole. The gas intake pipeline is provided with a temperature control module for heating the gas to a preset temperature.

In the present embodiment, the temperature control modules connected to the edge platforms in each concentric rings with a respective different radius have a respective different temperature regulation rate, and temperature control modules connected to edge platforms in a concentric ring with a larger radius (an inner ring, a secondary outer ring, and an outer ring in sequence) have a smaller temperature regulation rate.

Specifically, the event that temperature control modules connected to edge platforms in a concentric ring with a larger radius have a smaller temperature regulation rate includes: temperature control modules connected to edge platforms in each concentric ring with a different radius has a same gas injection flow rate and a respective different gas extraction flow rate, and temperature control modules connected to edge platforms in a concentric ring with a larger radius have a smaller gas extraction flow rate. In one example, the temperature regulation rate is controlled by the circulation rate of gas at a preset temperature. The concentric rings include an inner ring, a secondary outer ring, and an outer ring. The gas injection flow rate of the inner ring is 145000 Pa, and the gas extraction flow rate of the inner ring is 22000 Pa. The gas injection flow rate of the secondary outer ring is 145000 Pa, and the gas extraction flow rate of the secondary outer ring is 21850 Pa. The gas injection flow rate of the outer ring is 145000 Pa, and the gas extraction flow rate of the outer ring is 21700 Pa.

After the execution of action 205 is completed, a round of temperature control for the wafer on the bearing platform is completed, and action 202 is continued until no temperature abnormal region exists on the wafer.

It should be noted that the execution process of the above method further includes the following action. The temperatures of the wafer on the bearing platform are regulated to a preset temperature through constant-temperature liquid or constant-temperature gas.

Specifically, through constant-temperature liquid or constant-temperature gas with a preset temperature, the temperatures of the wafer on the bearing platform are changed towards the preset temperature. In one example, the preset temperature may be in a temperature range of 20° C. to 25° C., e.g., 21° C., 22° C., 23° C., and 24° C. In the present embodiment, the preset temperature is 22.5° C. since an optimum temperature of the wafer for exposure by the exposure machine table is 22.5° C. The temperature of the whole wafer is changed towards 22.5° C., so that the wafer is at the optimum temperature during exposure, and the efficiency of subsequent wafer exposure is improved.

Compared with the related art, the temperatures of a wafer on a bearing platform are acquired to acquire a temperature abnormal region of the wafer, i.e. to acquire a specific high-temperature position or a specific low-temperature position of the wafer. Then, an edge platform corresponding to the position of the temperature abnormal region of the wafer is acquired based on the temperatures of the wafer. The temperature of the temperature abnormal region of the wafer is regulated through a temperature control module connected to the edge platform. The temperature at the specific position of the wafer can be accurately controlled, thereby ensuring the uniform temperature distribution of the wafer.

Since the above embodiments correspond to the present embodiment, the present embodiment may be implemented in cooperation with the above embodiments. The related technical details mentioned in the above embodiments are still valid in the present embodiment, and the technical effects that can be achieved in the above embodiments may also be achieved in the present embodiment, which will not be described herein again for brevity. Accordingly, the related technical details mentioned in the present embodiment may also be applied to the above embodiments.

The above division of various actions is merely for clarity of description. During implementation, the actions may be combined into one action or some action may be split and decomposed into multiple actions, which may be within the scope of protection of this patent as long as the same logical relationship is included. It is within the scope of protection of this patent to add insignificant modifications to the process or to introduce insignificant designs without changing the core design of the process.

It will be appreciated by those of ordinary skill in the art that the various embodiments described above are particular embodiments for implementing the disclosure and that various changes in form and details may be made in practice without departing from the spirit and scope of the disclosure.

1. A temperature control system, applied to an exposure machine table, comprising:
a bearing platform configured to bear a wafer, wherein the bearing platform comprises a central platform and a plurality of edge platforms arranged around the central platform;
a plurality of temperature control modules, each connected to a respective edge platform and configured to regulate a temperature of a corresponding region of the wafer on the respective edge platform;
a parameter acquisition module, configured to acquire temperatures of the wafer on the bearing platform; and
a processing module, configured to acquire a temperature abnormal region of the wafer based on the temperatures of the wafer and regulate a temperature of a temperature control module corresponding to the temperature abnormal region.

2. The temperature control system of claim 1, wherein each edge platform comprises: a support member having a gas circulation region therein; and
the temperature control module connected to the edge platform is configured to introduce gas with a preset temperature into the gas circulation region based on a signal sent from the processing module.

3. The temperature control system of claim 2, wherein the support member comprises:
a gas extraction hole and a gas intake hole communicated with the gas circulation region, wherein
the gas extraction hole is configured to extract gas out of the gas circulation region; and
the gas intake hole is configured to introduce the gas with the preset temperature into the gas circulation region.

4. The temperature control system of claim 2, wherein the support member comprises:
an edge support portion, a first support portion, and a plurality of discrete second support portions, wherein
the edge support portion is arranged around the first support portion, and a gap exists between the edge support portion and the first support portion; and
the second support portions are located in the gap, and the gas circulation region is enclosed by the edge support portion, the first support portion, and the second support portions.

5. The temperature control system of claim 1, wherein the edge platforms arranged around the central platform form a plurality of concentric rings centered about the central platform.

6. The temperature control system of claim 5, wherein temperature control modules connected to edge platforms in each concentric ring with a respective different radius have a respective different temperature regulation rate, and temperature control modules connected to edge platforms in a concentric ring having a larger radius have a smaller temperature regulation rate.

7. The temperature control system of claim 1, further comprising: a constant-temperature pipeline filled with constant-temperature liquid or constant-temperature gas.

8. The temperature control system of claim 7, wherein the constant-temperature pipeline is located in gaps between the plurality of edge platforms.

9. The temperature control system of claim 7, wherein the constant-temperature liquid or the constant-temperature gas is in a temperature range of 20° C. to 25° C.

10. The temperature control system of claim 1, wherein the parameter acquisition module comprises a plurality of temperature sensors arranged at intervals or an infrared temperature sensor, configured to acquire temperatures at a plurality of positions of the wafer on the bearing platform; and
the processing module further comprises a processing sub-module, configured to acquire a temperature distribution map of the wafer based on the acquired temperatures at the plurality of positions of the wafer.

11. A temperature control method, applied to a temperature control system of claim 1, comprising:
acquiring temperatures of a wafer on a bearing platform;
acquiring, based on the temperatures of the wafer, a region of the wafer needing temperature regulation;
acquiring an edge platform corresponding to the region of the wafer needing temperature regulation; and
regulating a temperature of the region of the wafer needing temperature regulation through a temperature control module connected to the edge platform.

12. The temperature control method of claim 11, wherein the acquiring, based on the temperatures of the wafer, a region of the wafer needing temperature regulation comprises:
acquiring a temperature distribution map of the wafer based on temperatures at a plurality of positions of the wafer; and
acquiring, based on the temperature distribution map of the wafer, the region of the wafer needing temperature regulation.

13. The temperature control method of claim 11, further comprising:
regulating the temperatures of the wafer on the bearing platform to a preset temperature through constant-temperature liquid or constant-temperature gas.

14. The temperature control method of claim 13, wherein the preset temperature is in a temperature range of 20° C. to 25° C.

15. The temperature control method of claim 11, wherein temperature control modules connected to edge platforms in each concentric ring with a respective different radius have a respective different temperature regulation rate, and temperature control modules connected to edge platforms in a concentric ring with a larger radius have a smaller temperature regulation rate.

16. The temperature control method of claim 15, wherein the event that temperature control modules connected to edge platforms in a concentric ring with a larger radius have a smaller temperature regulation rate comprises:
temperature control modules connected to edge platforms in each concentric ring with a respective different radius have a same gas injection flow rate and a respective different gas extraction flow rate, and temperature control modules connected to edge platforms in a concentric ring with a larger radius have a smaller gas extraction flow rate.
